(19) United States
(12) Patent Application Publication
(10) Pub. No.: US 2008/0151659 A1
(43) Pub. Date: Jun. 26, 2008

(54) SEMICONDUCTOR MEMORY DEVICE

(75) Inventors: Kazuki Sakuma, Tokyo (JP); Jun Suzuki, Tokyo (JP); Chiaki Dono, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory Inc., Tokyo (JP)

(21) Appl. No.: 11/959,253

(22) Filed: Dec. 18, 2007

(30) Foreign Application Priority Data
Dec. 25, 2006 (JP) 2006-347199

(51) Int. Cl. G11C 7/00; G11C 29/00; G11C 8/00

(52) U.S. Cl. 365/200; 365/230.03; 365/201; 365/233.1

(57) ABSTRACT

A semiconductor memory device includes at least one memory bank. Each memory bank includes: memory units that output data in response to a burst read command; a selector section that sequentially outputs the data output from the memory units in accordance with a select signal; a comparator section that compares the data sequentially output from the selector section with reference data sequentially input, outputs a comparison result indicating normal when the data output from the selector section matches with the reference data, and outputs a comparison result indicating abnormal when the data output from the selector section does not match with the reference data; and a reduction result storage section that stores, as a reduction result of the memory bank, a value indicating normal when comparison results sequentially output from the comparator section all indicate normal, and a value indicating abnormal when any one of the comparison results indicates abnormal.

### BACKGROUND OF THE INVENTION

1. Field of the Invention

The present invention relates to a semiconductor memory device, and, particularly, to a semiconductor memory device having a test mode to reduce a test result for a plurality of memory units.

Priority is claimed on Japanese Patent Application No. 2006-347199 filed on Dec. 25, 2006, the content of which is incorporated herein by reference.

2. Description of the Related Art

The outline of a conventional dynamic random access memory (hereinafter called “DRAM”) will be described below.

Each of a memory array and a redundant memory array includes a plurality of memory cells each of which stores 1-bit data. The memory cells are grouped so that each group includes M memory cells (where M is an integer equal to or greater than 2). The individual memory cell groups are laid out at predetermined positions each determined by a row address and a column address. The memory array and the redundant memory array are accessed by a common row address.

A row and column address buffer generates a row address signal and a column address signal based on an address signal given externally, and sends the generated row address signal and column address signal to a row decoder and a column decoder, respectively.

The row decoder designates the row address of the memory array and redundant memory array in response to the row address signal given from the row and column address buffer.

The column decoder designates the column address of the memory array in response to the column address signal given from the row and column address buffer.

Provided in the column decoder and a redundant column decoder are fuses for programming the column address which includes defective memory cells in the memory array and the column address of the redundant memory array to replace that column address.

When a column address signal corresponding to the defective column address programmed by the fuses is input, the column decoder does not designate that column address, but the redundant column decoder designates the programmed column address of the redundant memory array instead of the former column address.

That is, a defective memory cell column in the memory array which includes defective memory cells is replaced with a normal memory cell column of the redundant memory array.

Conventionally, such a DRAM is tested by a tester to check if data writing and data reading are normal or abnormal.

The tester writes specific data in a memory element at an address selected in a memory module, and then detects if data read from the memory element at the address is identical to the written data. When the detection result indicates a match, the tester determines that data writing and reading are normal for the selected address, whereas when the detection result indicates otherwise, the tester determines that data writing and reading are abnormal for the selected address.

The tester detects if the memory module is normal or abnormal by executing a similar test for all the addresses of the memory module.

An address which is detected as abnormal in the test is stored in a redundant circuit, and is thereafter replaced with a normal address for defect repair by the redundant circuit.

Such a related art is disclosed in Japanese Unexamined Patent Application, First Publication No. H11-232896 (hereinafter referred to as Patent Document).

In the semiconductor memory device described in the Patent Document, however, a determination circuit, which has the same data written in memory cells beforehand and detects whether data writing and reading are abnormal or not, detects if two sets of data read from memory cells match with each other. When two sets of data are read from adjoining word lines and the adjoining word lines are short-circuited, the two sets of data have the same value, thus disabling normal detection.

### SUMMARY OF THE INVENTION

The present invention has been made in view of the foregoing circumstances, and it is an object of the present invention to provide a semiconductor memory device capable of normally detecting if data writing and reading are abnormal in a test mode even if adjoining word lines are short-circuited, and capable of performing detection by burst length and repairing defect when data writing and reading are abnormal.

A semiconductor memory device in accordance with the present invention comprises at least one memory bank, each memory bank including: a plurality of memory units that output data in response to a burst read command externally input; a selector section that sequentially outputs the data output from the plurality of memory units in accordance with a select signal externally input; a comparator section that compares the data sequentially output from the selector section with reference data sequentially and externally input, outputs a comparison result indicating normal when the data output from the selector section matches with the reference data, and outputs a comparison result indicating abnormal when the data output from the selector section does not match with the reference data; and a reduction result storage section that stores, as a reduction result of the memory bank, a value indicating normal when comparison results sequentially output from the comparator section all indicate normal, and a value indicating abnormal when any one of the comparison results indicates abnormal.

According to the present invention, in a test mode, it is possible to perform proper detection even if adjoining word lines are short-circuited, and ensure detection by burst length and repair defect when data writing and reading are abnormal.

In the present invention, the memory bank may further include a repair section that performs repair with memory cells corresponding to a same address in the plurality of memory units being taken as a repair unit, and the repair unit may be set equal to a burst length unit of the burst read command.

As a result, the present invention simplifies a circuit for defect repair.

In the present invention, a plurality of memory banks may be provided as the at least one memory bank, and the semiconductor memory device may further comprise a time-divisional output section that outputs reduction results output from reduction result storage sections, respectively provided in the plurality of memory banks, in a time-divisional manner.

As a result, the present invention can reduce the number of data output terminals to be used in the test mode.

In the present invention, the time-divisional output section may sequentially select the reduction results at a rising edge and a falling edge of a clock signal externally input and may output the reduction results in the time-divisional manner.

### BRIEF DESCRIPTION OF THE DRAWINGS

FIG. 1 is a schematic block diagram showing a structure in one bank in a semiconductor memory device in accordance with one embodiment of the present invention;

FIG. 2 is a structural diagram showing an example of the structure of a memory bank;

FIG. 3 is a circuit diagram showing an example of the circuit structure of a reduction result storage section;

FIG. 4 is a sequence diagram in the case where a reduction test for the structure in the bank in FIG. 1 is executed;

FIG. 5 is a schematic block diagram showing the structure in the case where the number of output terminals is reduced and the reduction result from a plurality of banks is output through the output terminals; and

FIG. 6 is a timing chart for explaining the operation of the structure shown in FIG. 5.

### DETAILED DESCRIPTION OF THE INVENTION

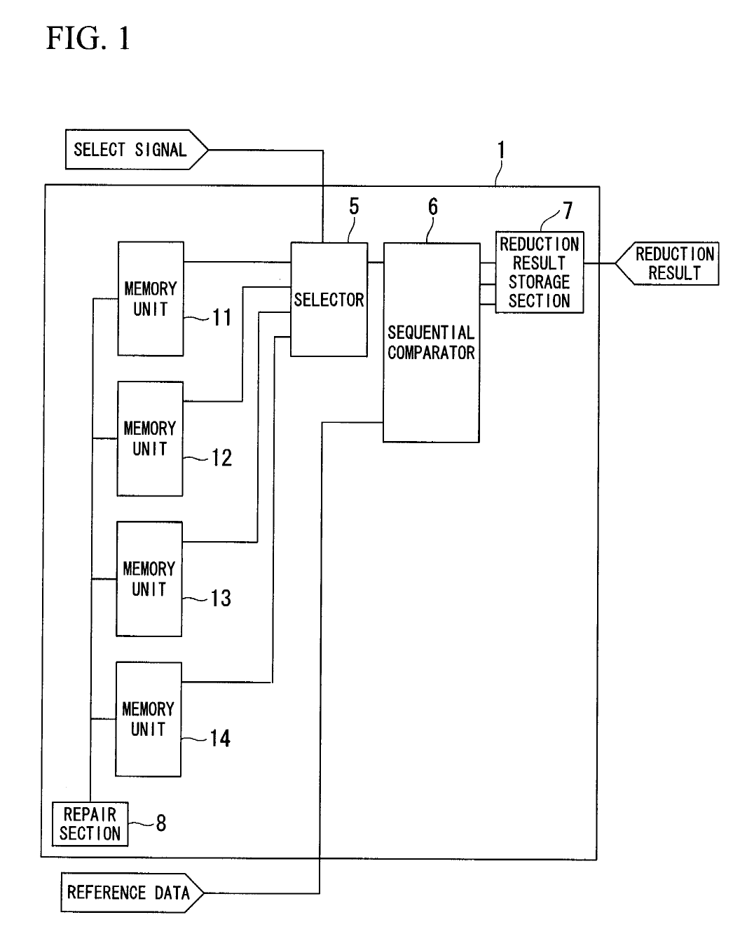

Embodiments of the present invention will now be described with reference to the accompanying drawings. FIG. 1 is a schematic block diagram showing a structure in one bank in a semiconductor memory device in accordance with the embodiment of the present invention.

A memory bank 1 includes memory units 11 to 14, a selector 5, a sequential comparator 6, a reduction result storage section 7, and a repair section 8.

In response to an address externally input and a burst read command, each of the memory units 11 to 14 outputs data corresponding to the input address. In response to a single burst read command, an address for selecting a same word line is input to the memory units 11 to 14.

As each of the memory units 11 to 14 outputs data, the semiconductor memory device outputs burst read data. In this example, by each of the memory units 11 to 14 outputting 1-bit data, 4-bit burst reading is carried out.

In this case, the burst length unit is “4” which is equal to the number of the memory units 11 to 14. That is, the burst length unit is 4 bits.

Each of the memory units 11 to 14 is a unit (e.g., mat) to store information, and stores data which is written therein externally. The written data is read outside from each of the memory units 11 to 14.

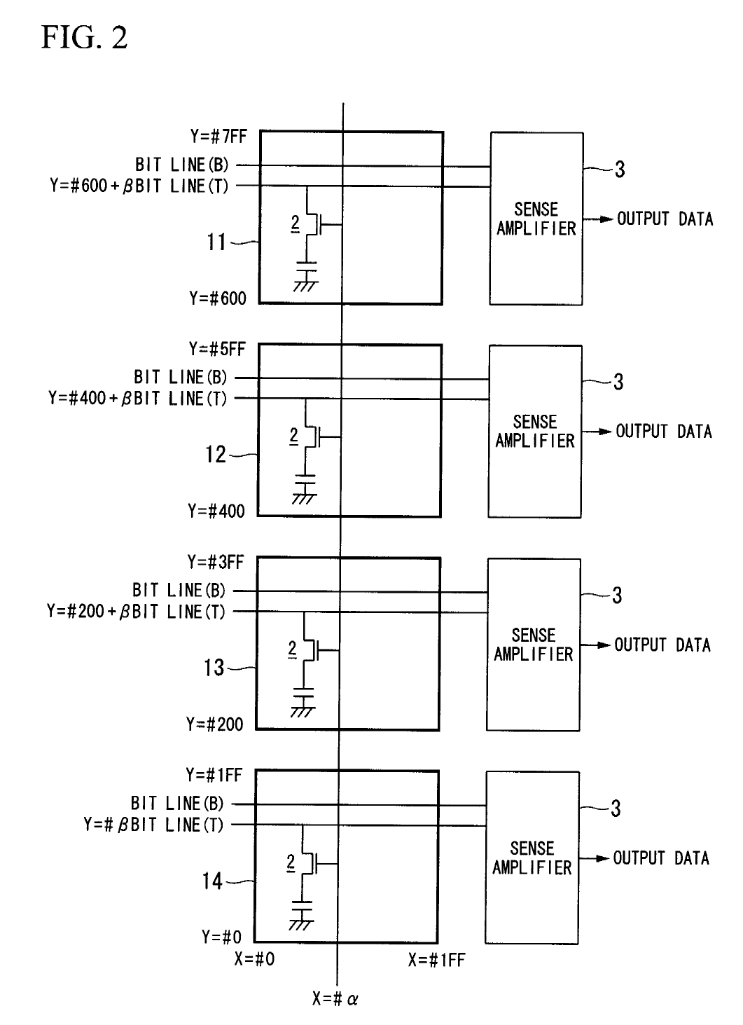

Referring to FIG. 2, a structural example of the memory units 11 to 14 will be described.

Each of the memory units 11 to 14 has memory cells 2 each designated by a bit line B, a bit line T and a word line X. Data stored in the memory cells 2 is output via a sense amplifier 3 provided for each memory unit.

As one example, bit addresses Y of the memory unit 14 correspond to 0 to 1FF (hexadecimal notation), bit addresses Y of the memory unit 13 correspond to 200 to 3FF, bit addresses Y of the memory unit 12 correspond to 400 to 5FF, and bit addresses Y of the memory unit 11 correspond to 600 to 7FF.

If a bit address Y of the memory unit 14 is beta, the bit addresses Y of each memory bank are designated taking the bit address Y of the memory unit 13 as 200+beta, the bit address Y of the memory unit 12 as 400+beta, and the bit address Y of the memory unit 11 as 600+beta.

Row addresses X of the memory units 11 to 14 are 0 to 1FF, and the row addresses of the memory units 11 to 14 are designated for a common word line X.

Returning to the description of FIG. 1, the selector 5 selects data to be output from the memory units 11 to 14 in accordance with a select signal externally input, and sequentially outputs the data to the sequential comparator 6.

That is, the selector 5 serially outputs data output in parallel from the memory units 11 to 14 to the sequential comparator 6 in accordance with the select signal externally input.

The sequential comparator 6 compares the data sequentially output from the selector 5 with reference data input externally. When the result of the comparison is a match, the sequential comparator 6 outputs the comparison result as normal, whereas when the comparison result is not a match, the sequential comparator 6 outputs the comparison result as abnormal.

The sequential comparator 6 is an exclusive OR circuit, for example.

The reduction result storage section 7 stores a value indicating normal as a reduction result for the memory units 11 to 14 when the comparison results sequentially output from the sequential comparator 6 are all matches, and stores a value indicating abnormal when any one of the comparison results is not a match.

The reduction result storage section 7 is a flip-flop, for example.

The reduction result storage section 7 outputs a stored reduction result to a corresponding output terminal in accordance with an external input read command (e.g., read command READ).

In starting a memory test, the reduction result storage section 7 is initialized to store a value indicating normal. Afterward, test results are sequentially input to the reduction result storage section 7, which stores a value indicating abnormal when the comparison result is not a match, and stores the value indicating abnormal thereafter until it is initialized.

The reduction result stored in the reduction result storage section 7 is a result for each repair unit in each memory bank, and is a 1-bit result indicating if the memory test has passed or failed (i.e., normal or abnormal).

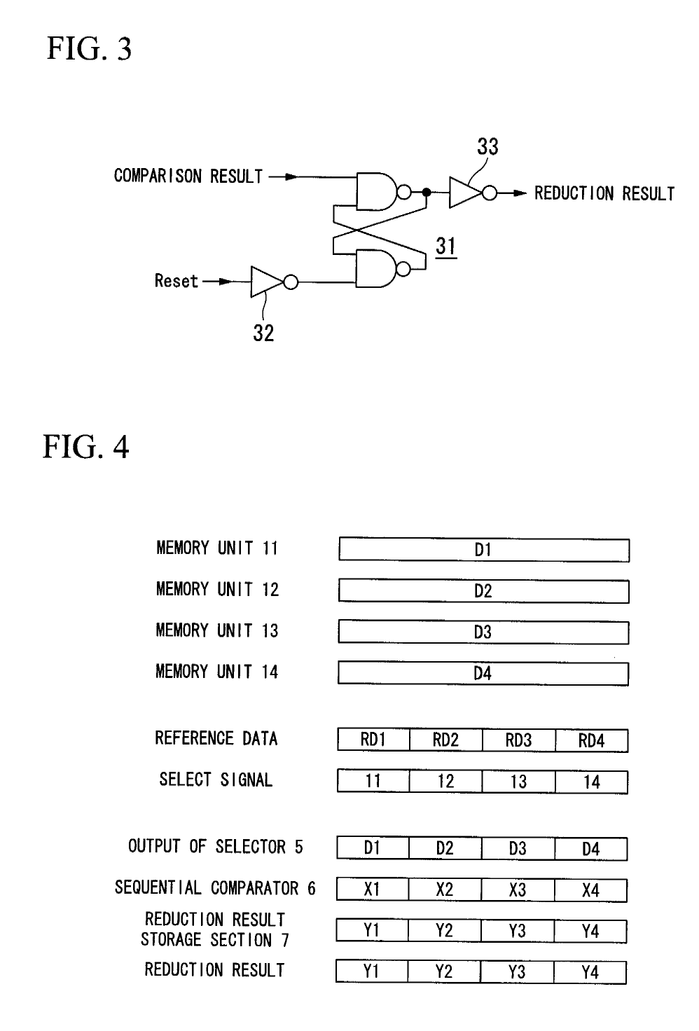

Referring to FIG. 3, an example of the circuit structure of the reduction result storage section 7 will be described.

The following description will be given of a case where it is normal when a reduction result output from the reduction result storage section 7 is H (high level) and it is abnormal when the reduction result is L (low level).

The reduction result storage section 7 can be realized by using, for example, an RS-FF (Flip-Flop) 31. A reset pulse RESET input externally at the time of executing the read command READ is input to the reset side of the RS-FF 31 through an inverter 32, L (low level) is output as the initial state of the RS-FF 31, and H (high level) is output via an inverter 33 as a reduction result.

Comparison results from the sequential comparator 6 are sequentially input to the set side of the RS-FF 31.

If even 1 bit of L (low level) which means a mismatch is present in the comparison result from the sequential comparator 6, the RS-FF 31 outputs H (high level) and the inverter 33 outputs L (low level) as a reduction result.

Returning to the description of FIG. 1, the repair section 8 performs repair with the same address of the memory units in each memory bank taken as a repair unit.

The repair section 8 stores, for example, one address to be repaired by setting fuses.

In this example, the burst length unit and the repair unit are set to the same value.

With the above-described structure, when even one abnormal is detected at the time of reading data by burst length, it is possible to execute repair with the burst length unit taken as the repair unit, thus facilitating the repair operation.

In other words, setting one repair unit equal to one burst length unit simplifies the circuit structure for the repair operation.

Since it is determined whether data writing and reading are normal or abnormal by comparing data sequentially output from the selector 5 with the reference data externally input, it is possible to properly determine whether data writing and reading are normal or abnormal even if adjoining word lines are short-circuited.

Referring now to FIG. 4, a description will be given of a case of executing a reduction test on the operation in one bank of the semiconductor memory device as shown in FIG. 1.

In starting the reduction test, the reduction result storage section 7 is initialized to store a value indicating normal.

First, the memory units 11 to 14 respectively output data D1 to D4 in response to a burst read command externally given.

As a select signal to select the memory unit 11 is externally input to the selector 5, the selector 5 selects the data D1 output from the memory unit 11 and outputs the selected data D1 to the sequential comparator 6.

The sequential comparator 6 receives the data D1 from the selector 5 and reference data RD1 externally input. The sequential comparator 6 compares the input data D1 and reference data RD1 with each other, and outputs a comparison result X1 to the reduction result storage section 7.

The reduction result storage section 7 stores the comparison result X1 input from the sequential comparator 6 as a reduction result Y1, and outputs the reduction result Y1. In this case, the comparison result X1 matches with the reduction result Y1.

Thereafter, as select signals to select the memory units 12 to 14 are externally input to the selector 5 in order, the selector 5 selects the data D2 output from the memory unit 12, the data D3 output from the memory unit 13, and the data D4 output from the memory unit 14 in order, and sequentially outputs the selected data D2 to D4 to the sequential comparator 6.

The sequential comparator 6 sequentially compares the data D2 to D4 sequentially output from the selector 5 with reference data RD2 to RD4 externally and sequentially input, and sequentially outputs comparison results X2 to X4 to the reduction result storage section 7.

That is, the sequential comparator 6 sequentially outputs the comparison result X2 from comparison of the data D2 from the memory unit 12 with the reference data RD2, the comparison result X3 from comparison of the data D3 from the memory unit 13 with the reference data RD3, and the comparison result X4 from comparison of the data D4 from the memory unit 14 with the reference data RD4 to the reduction result storage section 7.

The reduction result storage section 7 sequentially stores reduction results Y2 to Y4 based on the comparison results X1 to X4 sequentially input from the sequential comparator 6.

The value of the reduction result Y4 which is finally stored in the reduction result storage section 7 indicates normal if all of the comparison results X1 to X4 sequentially input from the sequential comparator 6 are normal, but indicates abnormal if any one of the comparison results X1 to X4 is abnormal.

In the above manner, a reduction result of burst reading from one memory bank is stored in the reduction result storage section 7 as 1-bit information indicating normal or abnormal.

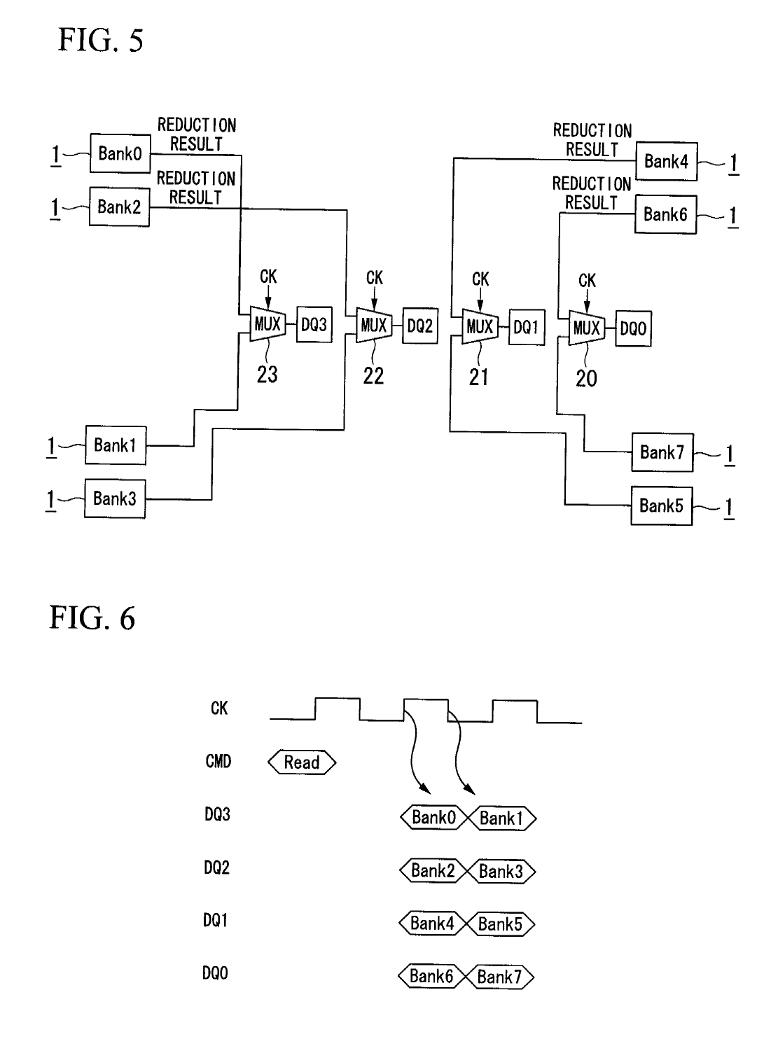

Referring now to FIG. 5, a description will be given of the structure that outputs reduction results from a plurality of banks while reducing the number of output terminals. The same reference numerals are given to those components in FIG. 5 which correspond to the individual components in FIG. 1 to avoid redundant descriptions.

Each the memory bank BANK0 to BANK7 shown in FIG. 5 has a structure similar to that of the memory bank 1 in FIG. 1. The reduction result storage sections 7 in the memory banks BANK0 to BANK 7 store reduction results of the associated memory banks BANK0 to BANK7.

For example, as an external tester writes reference data into the memory bank BANK0 and executes the reduction test which has been explained above referring to FIGS. 1 and 4, the reduction result of the reduction test is stored in the reduction result storage section 7 of the memory bank BANK0.

Similarly, as the external tester sequentially executes the reduction test on the memory banks BANK1 to BANK7 in the same manner as done for the memory bank BANK0, the reduction results of the reduction test on the memory banks BANK1 to BANK7 are stored in the reduction result storage sections 7 of the respective memory banks BANK1 to BANK7.

First, each of the memory banks BANK0 to BANK7 outputs a reduction result stored in its reduction result storage section 7 in response to a read command READ externally input.

Next, in synchronism with a clock signal CK externally input, time-divisional output sections 20 to 23 send reduction results output from the reduction result storage sections 7 of the memory banks BANK0 to BANK7 to output terminals DQ0 to DQ3 in a time-divisional manner.

Specifically, each of the time-divisional output sections 20 to 23 selects reduction results output from the reduction result storage sections 7 of two memory banks, switched from one to the other at the rising edge and falling edge of the externally input clock signal CK, and sends the selected reduction result to a corresponding terminal of the output terminals DQ0 to DQ3.

In this example, the time-divisional output section 23 time-divides the reduction results output from the reduction result storage sections 7 of the memory banks BANK0 and BANK1, and sends the time-divided reduction results to the output terminal DQ3.

The time-divisional output section 22 time-divides the reduction results output from the reduction result storage sections 7 of the memory banks BANK2 and BANK3, and sends the time-divided reduction results to the output terminal DQ2.

The time-divisional output section 21 time-divides the reduction results output from the reduction result storage sections 7 of the memory banks BANK4 and BANK5, and sends the time-divided reduction results to the output terminal DQ1.

The time-divisional output section 20 time-divides the reduction results output from the reduction result storage sections 7 of the memory banks BANK6 and BANK7, and sends the time-divided reduction results to the output terminal DQ0.

Referring now to FIG. 6, a description will be given of the operation of the structure shown in FIG. 5 which outputs reduction results while reducing the number of the output terminals.

First, the read command READ to read a reduction result is externally input.

Next, each of the memory banks BANK0 to BANK7 outputs a reduction result from the reduction result storage section 7 in response to the read command READ input.

In response to the read command READ, the time-divisional output section 23 sends the reduction result of the memory bank BANK0 to the output terminal DQ3 at the rising edge of the next cycle of the clock signal after the input of the read command READ, and sends the reduction result of the memory bank BANK1 to the output terminal DQ3 at the subsequent falling edge of the cycle of the clock signal.

At the same time, like the time-divisional output section 23, the time-divisional output sections 20 to 22 perform the following operations.

In response to the read command READ, the time-divisional output section 22 sends the reduction result of the memory bank BANK2 to the output terminal DQ2 at the rising edge of the next cycle of the clock signal after the input of the read command READ, and sends the reduction result of the memory bank BANK3 to the output terminal DQ2 at the subsequent falling edge of the cycle of the clock signal.

In response to the read command READ, the time-divisional output section 21 sends the reduction result of the memory bank BANK4 to the output terminal DQ1 at the rising edge of the next cycle of the clock signal after the input of the read command READ, and sends the reduction result of the memory bank BANK5 to the output terminal DQ1 at the subsequent falling edge of the cycle of the clock signal.

In response to the read command READ, the time-divisional output section 20 sends the reduction result of the memory bank BANK6 to the output terminal DQ0 at the rising edge of the next cycle of the clock signal after the input of the read command READ, and sends the reduction result of the memory bank BANK7 to the output terminal DQ0 at the subsequent falling edge of the cycle of the clock signal.

When the tester refers to the reduction results output from the output terminals DQ0 to DQ3 and detects that any reduction result indicates abnormal, repair information is stored in the repair section 8 of the memory bank which has output the reduction result indicating abnormal.

As described above, the use of the time-divisional output sections 20 to 23 can permit reduction results to be output from fewer output terminals DQ0 to DQ3.

This makes the chip size smaller and can reduce the number of output terminals to be used in a memory test even when the number of memory banks which can be measured simultaneously is limited by the number of pads of the chip. It is therefore possible to make the number of chips which can be measured simultaneously greater than that ensured by the conventional type which outputs reduction results in parallel for each repair unit, thereby improving the throughput of the memory test.

Although the output terminals DQ0 to DQ3 have been described only as output terminals in a test mode in the foregoing description of the present embodiment, the output terminals DQ0 to DQ3 are used as input/output terminals DQ0 to DQ3 in reading and writing data in a normal mode.

While preferred embodiments of the present invention have been described and illustrated above, it should be understood that these are exemplary of the present invention and are not to be considered as limiting. Additions, omissions, substitutions, and other modifications can be made without departing from the gist or scope of the present invention. Accordingly, the present invention is not to be considered as being limited by the foregoing description, and is only limited by the scope of the appended claims.

What is claimed is:

1. A semiconductor memory device comprising at least one memory bank, each memory bank including:
a plurality of memory units that output data in response to a burst read command externally input;
a selector section that sequentially outputs the data output from the plurality of memory units in accordance with a select signal externally input;
a comparator section that compares the data sequentially output from the selector section with reference data sequentially and externally input, outputs a comparison result indicating normal when the data output from the selector section matches with the reference data, and outputs a comparison result indicating abnormal when the data output from the selector section does not match with the reference data; and
a reduction result storage section that stores, as a reduction result of the memory bank, a value indicating normal when comparison results sequentially output from the comparator section all indicate normal, and a value indicating abnormal when any one of the comparison results indicates abnormal.

2. The semiconductor memory device as recited in claim 1, wherein the memory bank further includes a repair section that performs repair with memory cells corresponding to a same address in the plurality of memory units being taken as a repair unit, and the repair unit is set equal to a burst length unit of the burst read command.

3. The semiconductor memory device as recited in claim 1, wherein a plurality of memory banks are provided as the at least one memory bank, and the semiconductor memory device further comprises a time-divisional output section that outputs reduction results output from reduction result storage sections, respectively provided in the plurality of memory banks, in a time-divisional manner.

4. The semiconductor memory device as recited in claim 3, wherein the time-divisional output section sequentially selects the reduction results at a rising edge and a falling edge of a clock signal externally input and outputs the reduction results in the time-divisional manner.
